(19) United States
(12) Patent Application Publication
(10) Pub. No.: US 2026/0353530 A1
(43) Pub. Date: Nov. 5, 2026

(54) NON-DIGITAL LAYERED OPTICAL WINDOW SIMULATION SYSTEM

(71) Applicant: Eli Elad Cohen, Givatayim (IL)

(72) Inventor: Eli Elad Cohen, Givatayim (IL)

(21) Appl. No.: 19/651,948

(22) Filed: Apr. 20, 2026

Related U.S. Application Data
(60) Provisional application No. 63/799,579, filed on May 4, 2025.

(30) Foreign Application Priority Data
Dec. 10, 2025 (CN) 202522623590.X

(51) Int. Cl. H05B 45/20; H05B 45/10; H05B 47/11; H05B 47/16; H05B 47/19; H05K 5/30

(52) U.S. Cl. CPC H05B 45/20; H05B 45/10; H05B 47/11; H05B 47/16; H05B 47/19; H05K 5/30

(57) ABSTRACT

A non-digital layered optical window simulation system comprises a housing frame defining a viewing area with a window partition element, a front glass, and a graphic insert positioned immediately rearward of the front protective panel incorporating light-blocking opaque zones simulating a window frame border, vertical mullion, and horizontal transom dividing the viewing area into four pane zones. An LED panel is disposed rearward of the insert and configured with a plurality of LED strips and an integral light-diffusing element. A circadian controller simultaneously drives the CCT and RGB arrays, extending light simulation across the full spectrum of natural and celestial illumination conditions. A Wi-Fi smart LED controller supports mobile application control, voice assistant integration, scheduling, and weather synchronization. Sawtooth-profile hangers enable wall-mounted or ceiling-mounted installation without modification. All high-voltage components are external to the LED panel cavity, enabling Class 2 luminaire safety certification.

### CROSS-REFERENCE TO RELATED APPLICATIONS

This application claims the benefit of priority to U.S. Provisional Patent Application No. 63/799,579, filed May 4, 2025, and to Chinese Utility Model Application No. 202522623590.X, filed Dec. 10, 2025, the entire disclosures of which are incorporated herein by reference.

### FIELD OF THE INVENTION

The present invention relates to architectural lighting, optical simulation, ambient illumination, and interior augmentation devices, and more particularly, relates to a wall-mountable or ceiling-mountable non-digital layered optical assembly that simulates a natural window in interior spaces.

### BACKGROUND OF THE DISCLOSURE

A substantial proportion of modern interior spaces—including basement offices, interior commercial rooms, hospitality suites, healthcare facilities, and residential spaces—lack access to natural windows. Clinical and occupational research has associated the absence of natural light and outdoor visual connection with impaired circadian rhythm, reduced cognitive performance, diminished mood, increased incidence of Seasonal Affective Disorder (SAD), and reduced occupant wellbeing. Conventional approaches to addressing this deficiency fall into several categories, each suffering from material limitations.

SAD light therapy lamps, including products such as Verilux HappyLight, Carex Day-Light Classic, and Lumie Arabica, deliver high-intensity white light (10,000 lux) for mood therapy. These devices present as flat, featureless light panels with no window form factor, no outdoor scene simulation, no depth illusion, no architectural integration, and no color temperature variation for scene simulation. Relevant prior art includes CN201672371U and CN203811981U.

LED ceiling panels and flat LED light boxes, including commodity LED panel lights and photography lightboxes, provide planar illumination with no layered optical structure, no depth effect, no structural window simulation, no interchangeable scenic inserts, and no smart control oriented toward outdoor scene simulation. Relevant prior art includes CN108845775A and CN210136704U.

Digital window and skylight simulation displays, including products such as Sky Factory Healing HealthScapes, CoeLux LED skylight, and Mitsubishi Electric virtual window, use LCD, OLED, or LED matrix video screens to display moving or static outdoor imagery. While capable of convincing visual scene reproduction, such systems are prohibitively expensive (USD $3,000-$30,000+), consume substantial power, require content management systems, exhibit visible screen bezels and pixel artifacts that undermine realism, present a flat screen surface that fails to replicate the visual depth of looking through a physical glazed pane, and are subject to screen degradation and component obsolescence. Relevant prior art includes US20230145323A1, CN117409685A, and CN117409686A.

Smart ambient lighting systems, including Philips Hue White Ambiance, LIFX, and Nanoleaf Skylight, provide color-tunable LED output for general ambient use but offer no visual outdoor scene simulation, no window form factor, no optical depth effect, and no structural window realism. Decorative backlit window panels, including faux window art with LED frames commercially available through various retailers, are limited to a single optical layer, produce a flat and unconvincing simulation, and provide no dynamic lighting control, no modular insert system, and no structural window element simulation.

A limitation common to all prior art ambient lighting and window simulation products is a narrow effective color temperature range. Industry-standard tunable-white (CCT) LED technology operates within a range of approximately 2,700K-6,500K. This range is insufficient to reproduce extreme warm natural light conditions—including candlelight (≈1,000-1,800K), firelight, and deep golden-hour sunset (≈1,800-2,500K)—or extreme cool conditions—including heavy overcast sky (≈7,000K), high-altitude clear-sky daylight (≈8,000-10,000K), moonlight, and starfield night. No prior art window simulation, or ambient lighting product combines independently operable tunable-white CCT and RGB LED outputs to extend effective light simulation beyond this standard range.

Accordingly, there exists a long-felt and unmet need for a non-digital, low-cost, architecturally integrated device that combines: optical window simulation with physical depth cues; structural window realism including frame, mullion, and transom simulation; dynamic full-spectrum scene lighting covering natural and celestial illumination conditions; modular user-replaceable scenic content; smart home integration and circadian rhythm support; and dual-orientation installation capability—all in a single product free of digital screen technology.

### SUMMARY OF THE DISCLOSURE

It is an objective of the present invention to provide a non-digital layered optical window simulation system that replicates the visual, structural, and psychological experience of a natural window in interior spaces lacking natural fenestration, without the use of any digital screen, LCD, OLED, or LED matrix display technology.

It is a further objective of the present invention to provide a multi-layer optical assembly comprising a front protective panel, a graphic insert positioned immediately rearward of the front protective panel, an LED panel, and a back panel, wherein the physical layered arrangement of these components, causes the printed outdoor scene to appear set back from the front protective panel surface, creating an optical depth cue consistent with viewing through a real glazed window pane.

It is a further objective of the present invention to provide a window partition element that divides the viewing area into a plurality of pane zones by means of light-blocking opaque zones of no less than 95% optical density, simulating the structural elements of a real window including a frame border, vertical mullion, and horizontal transom.

It is a further objective of the present invention to provide a circadian controller configured to simultaneously and independently drive a tunable-white CCT LED array and an RGB color LED array within the LED panel, thereby extending the effective light simulation range to approximately 1,000 kelvins to 10,000 kelvins equivalent and enabling reproduction of the full spectrum of natural and celestial illumination conditions, from candlelight and firelight through golden-hour sunset, midday daylight, overcast sky, high-altitude blue sky, moonlight, and starfield night.

It is a further objective of the present invention to provide a graphic insert that is user-replaceable without tools, enabling ongoing scene customization over the product lifecycle without replacement of the system, and that incorporates a printed outdoor scene on UV-printed PET backlit film optimized for vivid color reproduction under backlight illumination.

It is a further objective of the present invention to provide a programmable circadian lighting system with time-of-day scheduling via a real-time clock, supporting automatic diurnal light cycling that promotes circadian rhythm alignment and occupant wellbeing.

It is a further objective of the present invention to provide smart home integration via a Wi-Fi smart LED controller supporting mobile application control, voice assistant integration with Amazon Alexa, Google Assistant, and Apple HomeKit, IFTTT conditional automation, and real-time weather API synchronization that automatically adjusts the active lighting scene to correspond with current outdoor meteorological conditions.

It is a further objective of the present invention to provide a dual-orientation mounting system comprising sawtooth-profile hangers on the rear surface of the housing frame, enabling installation of the system as a wall-mounted vertical window simulation or a ceiling-mounted horizontal skylight simulation without modification to the system.

It is a further objective of the present invention to provide a system in which all high-voltage electrical components are housed external to the LED panel cavity, enabling the system to qualify as a Class 2 luminaire under applicable safety standards including UL 1310, ETL/UL 8750, FCC Part 15 B+C, CE, and RoHS.

It is a further objective of the present invention to provide a low-cost non-digital window simulation solution having a target retail price substantially below that of digital window simulation alternatives, making the benefits of window simulation accessible to residential, commercial, and therapeutic users.

It is a further objective of the present invention to provide a modular and customizable system in which the graphic insert, housing frame finish, handle, and optional accessories including decorative curtains, faux blinds, and window handle hardware can be independently replaced or upgraded without replacing the complete system.

It is a still further objective of the present invention to provide a system that simultaneously functions as an ambient lighting fixture, a decorative architectural window element, a mood enhancement device, and a circadian rhythm support tool, without requiring any digital content subscription, active display technology, or ongoing maintenance beyond optional graphic insert replacement.

It is a further objective of the present invention to provide a system that is not limited to window simulation but is applicable to any non-digital layered optical scene simulation context including skylight, nature scene, retail, therapeutic, and wellness lighting applications.

These and other objectives and advantages of the present invention will become apparent from the following detailed description, taken in conjunction with the accompanying drawings.

### BRIEF DESCRIPTION OF THE DRAWINGS

The accompanying drawings are incorporated herein and form a part of the specification. They illustrate embodiments of the invention and, together with the description, serve to explain the principles of the invention. Like reference numerals designate corresponding parts throughout the several views.

FIG. 1 is a front elevation view of a non-digital layered optical window simulation system in an assembled, operable condition according to an embodiment of the present invention.

FIG. 2 is an exploded perspective view of a non-digital layered optical window simulation system.

FIG. 3 is a rear-elevation view of the non-digital layered optical window simulation system illustrating the Wi-Fi control and power subsystems.

FIG. 4 is an exploded perspective view of the non-digital layered optical window simulation system.

FIG. 5 is an LED panel with LED strips attached to a back panel of the simulation system.

FIG. 6 is a set of front-elevation environmental views illustrating the non-digital layered optical window simulation system installed on an interior wall and operating under three different programmable lighting scene presets, including a daylight scene, a night scene, and an overcast or rainy-weather scene.

FIG. 7 is a set of front-elevation environmental views illustrating the non-digital layered optical window simulation system installed on an interior wall and operating under two additional programmable lighting scene presets, including a midday daylight scene and a golden-hour or sunset scene.

### DETAILED DESCRIPTION OF THE DISCLOSURE

The following detailed description is presented to enable any person skilled in the art to make and use the invention. Specific details are set forth to provide a thorough understanding of the present invention. The invention is not limited to the particular embodiments described; it is intended to cover modifications, equivalents, and alternatives falling within the spirit and scope of the appended claims. Further, the specific values, ranges, dimensions, and material specifications set forth herein are provided for purposes of illustration only and represent preferred reference embodiments. Unless expressly recited in the claims, such values are not intended to limit the scope of the invention, and equivalent results may be achieved using values outside the ranges described.

While the following description presents example embodiments in the context of a natural window simulation system, it will be understood that the invention is not limited to window simulation applications. The principles, structures, and methods described herein are equally applicable to other scene simulation and ambient lighting contexts, and references to window elements such as a frame, mullion, transom, and pane zones are illustrative of one preferred embodiment and are not limiting on the scope of the claimed invention.

As used herein, the term “non-digital layered optical window simulation system,” “non-digital optical illumination apparatus,” “non-digital optical scene simulation apparatus,” or “system” refers to the complete apparatus 100. The term “housing frame” refers to a structural outer enclosure 102. The term “window partition element” refers to a structural element 104 that divides the viewing area into multiple pane zones, simulating the frame, mullion, and transom of a real window. The term “handle” refers to a decorative latch hardware element 106. The term “front protective panel” refers to a transparent forward-facing panel, a glass or any transparent material 110. The term “graphic insert” refers to a printed translucent scenic film 120, positioned immediately rearward of a front protective panel 110. The term “LED panel” refers to an LED strip array assembly 140. The term “back panel” refers to a rear housing tray 170. The term “wire” or “power cable” refers to an electrical connection harness 150. The term “circadian controller” refers to a multi-channel LED control module 160. The term “AC-DC adapter” refers to an external power supply unit 202. The term “Wi-Fi smart LED controller” refers to a wireless control module 204. The term “hanger” refers to a rear-mounted wall and ceiling mounting bracket 206. The term “LED strip” refers to a SMD LED strip components 402 within the LED panel 140. The term “ON/OFF switch” refers to a physical power switch 404. “CCT” means correlated color temperature in kelvins. “RGB” refers to independently controllable red, green, and blue LED channels. “CRI” means color rendering index. “PWM” means pulse-width modulation. “OTA” means over-the-air firmware update. “RTC” means real-time clock. “PET” means polyethylene terephthalate. “PMMA” means polymethyl methacrylate.

As used herein, the term “extended light simulation range” or “extended effective color temperature range” refers to a perceived correlated color temperature range achieved through combined spectral output of a tunable-white CCT LED array and an RGB LED array, wherein the resulting emitted light exhibits spectral characteristics corresponding to color temperatures outside the native operating range of the tunable-white LED array alone.

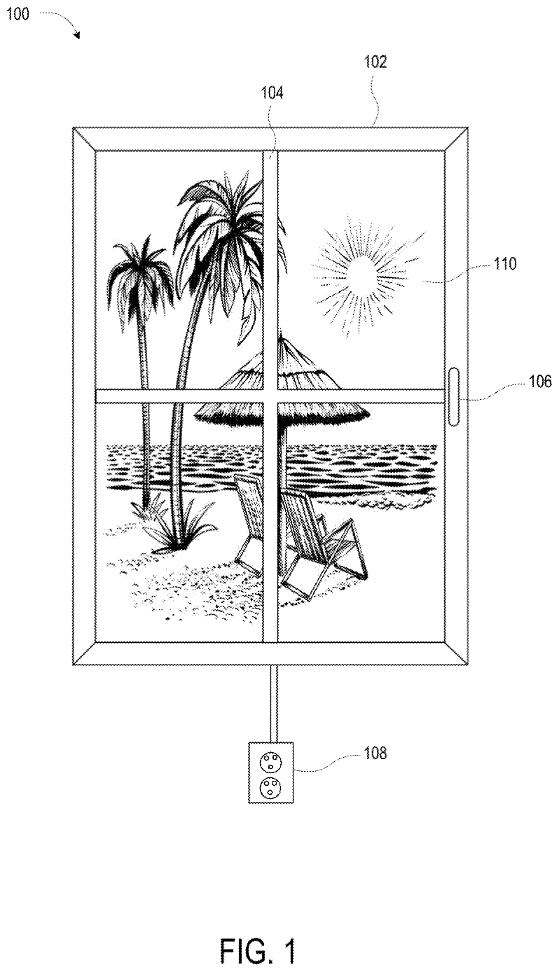

Referring now to FIG. 1, according to an exemplary embodiment of the present invention, a non-digital layered optical window simulation system 100 is shown in a fully assembled, operable condition as installed on an interior wall surface. The system 100 simulates the visual, structural, and psychological experience of a natural glazed window for occupants of interior spaces lacking access to natural fenestration.

A housing frame 102 forms the structural outer enclosure of the system 100. In the reference embodiment, the housing frame 102 is fabricated from 6063-T5 aluminum extrusion, powder-coated, with an overall outer dimension of 630 mm (width)×934 mm (height)×35 mm (depth) for the Standard size, or 934 mm (width)×1,244 mm (height)×35 mm (depth) for the Large size. The frame border is 30 mm on all sides. Alternative structural materials compliant with applicable flammability standards (ABS, polycarbonate, or other rigid materials meeting UL 94 requirements) are within the scope of the invention. Finishes include matte white, matte black, wood-grain texture, and custom colors. The housing frame 102 operates across 0-40 °C and stores within −10-50 °C. These dimensions are illustrative of preferred commercial sizes and are not limiting.

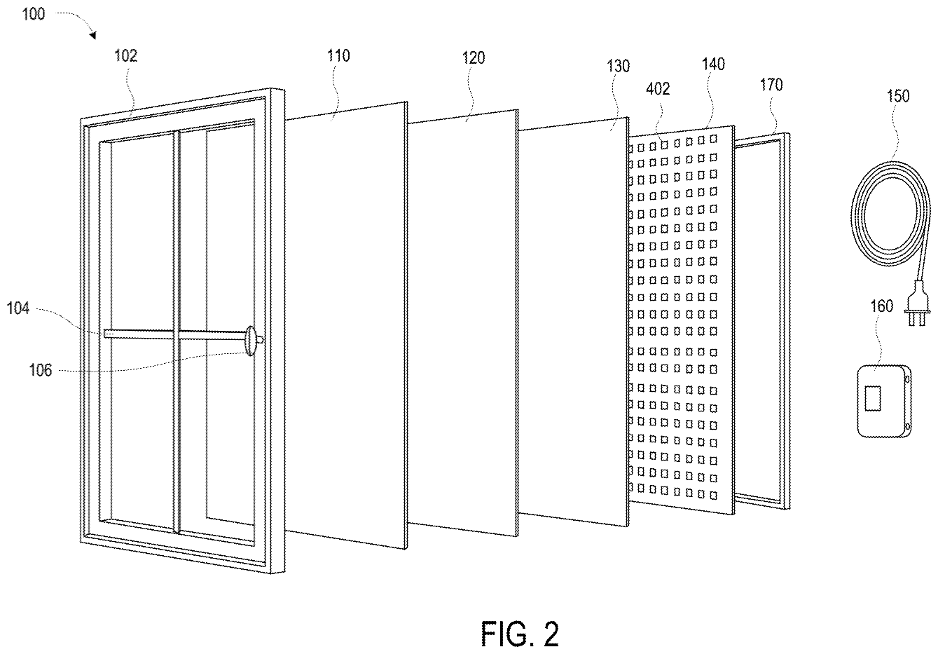

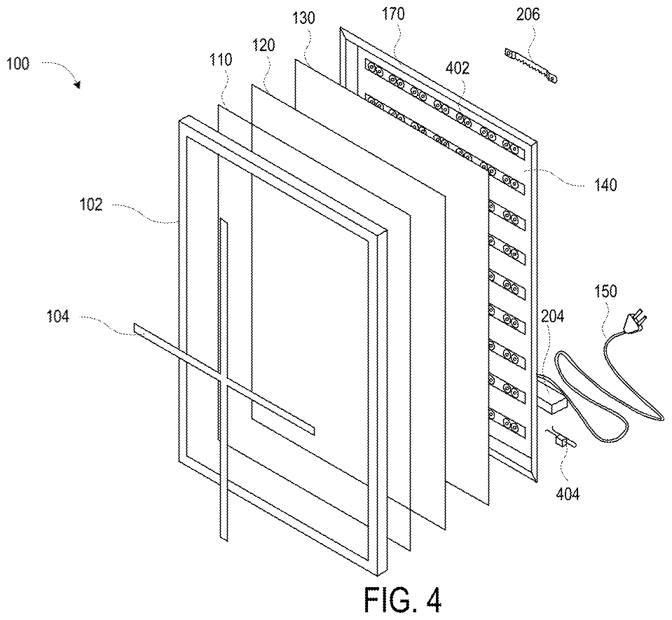

Referring to FIG. 1, FIG. 2, and FIG. 4, a window partition element 104 divides the viewing area of the system 100 into multiple pane zones, simulating the frame border, vertical mullion, and horizontal transom of a real window. In the reference embodiment, the window partition element 104 is formed by physical elements of the housing frame 102 and by corresponding opaque light-blocking zones on the graphic insert 120, wherein a vertical center mullion of approximately 20 mm width and a horizontal center transom of approximately 20 mm width divide the transparent viewing area into four pane zones each measuring approximately 275 mm×427 mm (Standard size). These dimensions are illustrative of the Standard size reference embodiment and are not limiting. Opaque zones achieve no less than 95% optical density and are formed from black ink printing, aluminum foil laminate, or opaque vinyl laminate.

A handle 106 is a decorative accessory attached to the exterior right-side face of the housing frame 102, simulating the latch hardware of a real casement window. The handle 106 is user-replaceable and configurable in multiple finish and profile variants.

In the exemplary embodiment, the system includes a front protective panel 110, for example a glass or a glass panel, which is the transparent forward-facing panel at the forwardmost position of the optical layer stack, flush with the front face of the housing frame 102. In the reference embodiment, the front protective panel 110 is 1.5 mm clear PMMA acrylic sheet, scratch-resistant. Polycarbonate sheet is an alternative material. The front protective panel 110 provides mechanical surface protection for the graphic insert 120 and presents a transparent “glazing” surface consistent with a real glass window pane. The graphic insert 120 is positioned immediately rearward of the front protective panel 110. As further shown in FIG. 1, the system 100 is electrically connected via the power cable 150 to an electrical outlet 108, which is a standard wall-mounted AC power receptacle external to the system 100 and provided in the interior space in which the system 100 is installed.

Referring now to FIG. 2, the complete multi-layer optical assembly of the system 100 is shown in exploded perspective view. The layers are arranged from front to rear: the front protective panel 110; a graphic insert 120 (immediately rearward of the front protective panel 110); an LED panel 140; a back panel 170; with a power cable 150 providing electrical interconnection and a circadian controller 160 managing the LED panel 140. This multi-layer assembly is fundamentally distinct from both flat single-layer backlit panels and digital screen-based window simulation systems.

The graphic insert 120 is a high-resolution static outdoor scene printed on a translucent substrate, disposed immediately rearward of the front protective panel 110. In the reference embodiment, the graphic insert 120 is UV-printed PET backlit film, 0.27-0.31 mm thick, semi-matte or satin finish, printed at 1,440-2,400 dpi. These material specifications are illustrative of the reference embodiment only. The graphic insert 120 may depict any outdoor scene including tropical beach, forest, mountain landscape, urban skyline, sky and clouds, garden, ocean, or starfield. The graphic insert 120 incorporates the light-blocking zones forming the window partition element 104: an outer border zone of approximately 30 mm width; a vertical center mullion of approximately 20 mm width; and a horizontal center transom of approximately 20 mm width. The graphic insert 120 is user-removable and user-replaceable without tools via a top-loading slot or by release of the front frame.

A physical inter-layer air gap is maintained between the rearward face of the graphic insert 120 and the forward face of the LED panel 140. In the reference embodiment, this spacing is approximately 1-10 mm and is established by spacer elements integrated into the inner lip geometry of the housing frame 102 or by the insert holder geometry. The specific air gap dimension is illustrative; any spacing producing the described optical depth effect is within scope.

The LED panel 140 is the main illumination assembly, disposed rearward of the graphic insert 120, housing the LED strips 402 and a light-diffusing element 130. The LED panel 140 comprises a plurality of LED strips 402 mounted in horizontal rows within the LED panel 140 using high-thermal-conductivity adhesive, operating at 24V DC. The LED panel 140 incorporates: a tunable-white CCT array (warm-white and cool-white channels, 2,200K-7,500K; reference minimum 2,700K-6,500K); and an RGB array (independently controllable red, green, and blue channels). CRI exceeds 90, total luminous flux is 6,500-7,500 lumens (Standard), and total power consumption is 60-72 W. Passive aluminum heat dissipation limits maximum LED surface temperature to 50 °C at full load. These specifications reflect the reference embodiment and are illustrative only.

The light-diffusing element 130 is disposed between the LED strips 402 and the rearward face of the graphic insert 120. The light-diffusing element 130 is a translucent planar panel fabricated from frosted PMMA, PET, or PVC material, having a light transmittance selected to balance forward lumen output with complete elimination of visible LED point-source artifacts. In the reference embodiment, the diffusing element transmittance maximizes luminous efficacy while ensuring that no individual LED element within the LED strips 402 is perceptible to a viewer at normal viewing distance, such as 1 to 3 meters from the front protective panel 110.

Natural daylight passing through a real glass window pane produces smooth, spatially uniform illumination with no visible point sources. The light-diffusing element 130 replicates this characteristic by scattering the output of the LED strips 402 into a continuous, even luminous field across the full area of the graphic insert 120 and viewing aperture. The uniform illumination ensures that the printed outdoor scene on the graphic insert 120 is evenly backlit in a manner consistent with ambient outdoor light, without localized bright spots or dark regions that would undermine the realism of the window simulation.

The elimination of hot spots is achieved through the effect of one or more of following geometric factors: the transmittance and scattering characteristics of the diffusing element material; the physical distance between the LED strips 402 and the forward face of the diffusing element 130 within the LED panel 140 cavity; and the pitch spacing between adjacent LED strips 402 within the LED panel 140.

The back panel 170 is the rear housing tray of the system 100, forming the structural enclosure of the LED panel 140 and providing the mounting surface for the LED strips 402. The back panel 170 is fabricated from aluminum or equivalent material with high thermal conductivity for passive heat dissipation. The power cable 150 is the electrical connection harness interconnecting the LED panel 140 with the circadian controller 160, AC-DC adapter 202, and Wi-Fi smart LED controller 204. The circadian controller 160 manages simultaneous independent PWM control of the CCT and RGB arrays within the LED panel 140, executing scene profiles as paired CCT+RGB recipes, and incorporates an RTC for time-based scene automation.

The electrical system of the apparatus operates as follows. The AC-DC adapter 202 receives AC power from a standard electrical outlet via the power cable 150 and converts it to regulated 24V DC output. The 24V DC output of the AC-DC adapter 202 is supplied to the Wi-Fi smart LED controller 204, which distributes regulated 24V DC power to the LED panel 140 and LED strips 402 via the power cable 150. The circadian controller 160 receives control signals from the Wi-Fi smart LED controller 204 and generates independent PWM output signals to the CCT array and RGB array of the LED strips 402, controlling color temperature, intensity, and spectral composition in real time. User commands originate from the mobile application or voice assistant platform, are transmitted over the local Wi-Fi network to the Wi-Fi smart LED controller 204, and are interpreted by the circadian controller 160 to execute the corresponding scene profile. The ON/OFF switch 404 is wired in series between the AC-DC adapter 202 output and the Wi-Fi smart LED controller 204 input, interrupting all power to the system when engaged regardless of the wireless control state.

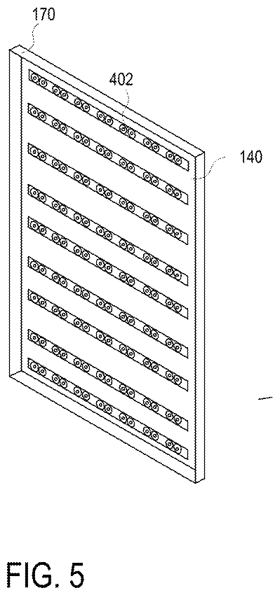

Referring now to FIG. 5, an enlarged detail view of the LED strip 402 within the LED panel 140 is shown. The LED strip 402 comprises a plurality of LED elements operating at 24V DC with a CCT tunable-white range of 2,700K-6,500K, CRI exceeding 90, and a power density of 12-15 W/m. Approximately four meters of LED strip 402, comprising approximately 64 pairs of CCT LED elements, are mounted within the LED panel 140 in horizontal rows. This configuration, confirmed by prototype component testing with OSRAM-branded or equivalent LED strips, delivers the multi-spectrum illumination capability central to the window simulation function of the system 100.

The simultaneous, independent control of the CCT array and the RGB array within the LED panel 140, managed by the circadian controller 160, extends the effective simulated light temperature range to approximately 1,000K-10,000K equivalent, covering: candlelight and firelight (≈1,000-1,800K)—minimum CCT warm-white combined with elevated RGB red and amber; golden-hour and sunset (≈1,800-2,500K)—CCT warm-white with RGB warm-amber; midday daylight (≈5,500-6,500K)—CCT cool-white alone; overcast sky (≈6,500-7,500K)—CCT cool-white with elevated RGB blue; clear high-altitude blue sky (≈8,000-10,000K)—CCT cool-white with substantially elevated RGB blue; moonlight (≈4,100K at low intensity)—dimmed CCT mid-white with low RGB cool; and starfield and night sky—RGB blue dominant with CCT at minimum. This combined simultaneous CCT and RGB technique for full-spectrum celestial light simulation is novel and not present in any prior art window simulation, or ambient lighting product. The specific kelvin values cited are illustrative of representative natural and celestial conditions and are not limiting.

The extension of the effective color temperature range is achieved through additive spectral blending, wherein RGB channels introduce supplementary wavelength components that shift the perceived chromaticity of the emitted light beyond the native limits of the tunable-white CCT LED channels. Such extended chromaticity outputs are not achievable by operation of the tunable-white CCT array alone, nor by operation of the RGB array alone, but instead result from coordinated simultaneous control of both arrays. This combined spectral control enables accurate simulation of natural and celestial illumination conditions across a range extending below conventional warm-white limits and above conventional cool-white limits of standard tunable-white lighting systems.

In certain embodiments, the resulting output corresponds to non-native correlated color temperature values that are perceptually equivalent to lighting conditions outside the intrinsic operating range of the CCT LED array.

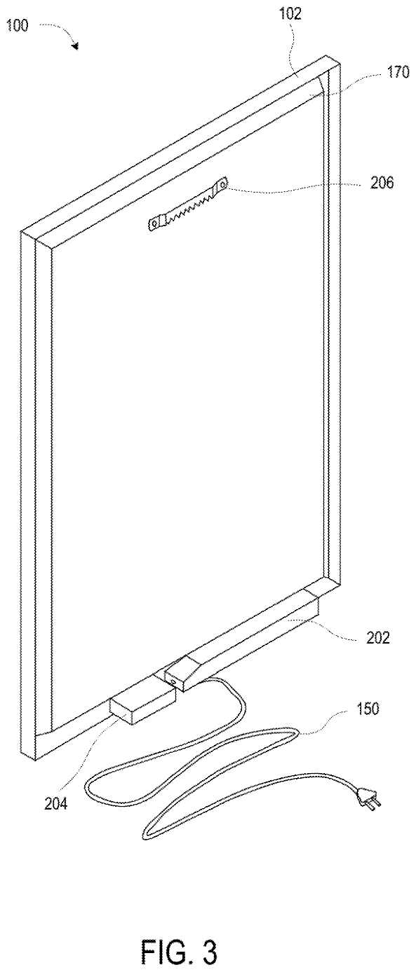

Referring now to FIG. 3, the rear-elevation view shows the mounting and power subassemblies. The back panel 170 forms the rear face of the system 100. The cable 150 connects the power subassembly to the LED panel 140 and circadian controller 160. The AC-DC adapter 202 is an external Class 2 constant-voltage LED driver providing 24V DC at 5 A continuous output from universal AC input (100-240V AC, 50/60 Hz), housed in a slim bar-shaped form factor in the bottom exterior compartment of the housing frame 102. All high-voltage components remain external to the LED panel cavity, supporting Class 2 safety certification under UL 1310 and ETL standards. The Wi-Fi smart LED controller 204 is housed alongside the AC-DC adapter 202 in the bottom compartment.

In one aspect, the system includes a hanger 206, for example, a metal sawtooth-profile mounting bracket fixed symmetrically on the back panel 170. In some aspects, the hanger 206 may be mounted on the housing frame 102. In some embodiments, two identical hangers 206 are provided in the upper region, each with a sawtooth-profile edge engaging standard wall or ceiling screws with horizontal adjustment in discrete pitch increments. In the vertical installation orientation, the two hangers 206 engage wall screws, installing the system 100 as a wall-mounted window simulation. In the horizontal installation orientation, the same hangers 206 engage ceiling fasteners, installing the system 100 as a ceiling-mounted skylight simulation. No modification to the system 100 is required to transition between orientations.

Referring now to FIG. 4, the combined assembly view shows all major components. The housing frame 102 encloses the optical assembly: the front protective panel 110, the graphic insert 120, the LED panel 140, and the back panel 170. The wire 150 interconnects the LED panel 140 with an AC-DC adapter 202 and a Wi-Fi smart LED controller 204 in the bottom exterior compartment. The hanger 206 is visible on the rear surface. The LED strip assembly 402 is shown within the LED panel 140. A power control switch 404, also referred to as an ON/OFF switch 404, is mounted on the exterior edge of the housing frame 102, providing manual power control independent of the Wi-Fi smart LED controller 204 and mobile application. Light propagates from the rear of the assembly to the front in the following sequence. The LED strip 402 emits light forwardly through the diffusing element integral to the LED panel 140, which eliminates all visible point-source hot spots and produces smooth, uniform illumination across the full viewing area. The diffused light then passes through the graphic insert 120, wherein the transparent scenic zones transmit the printed outdoor scene and the opaque zones of the window partition element 104 block transmission through the mullion and transom regions, reinforcing the structural window illusion. The transmitted light then passes through the front protective panel 110 and outward into the room interior. The physical placement of the graphic insert 120 immediately behind the front protective panel 110, with the LED panel 140 and back panel 170 recessed further rearward within the housing frame 102, causes the scenic image to appear set back from the front protective panel surface, producing the optical depth perception that is central to the window simulation effect of the present invention.

The Wi-Fi smart LED controller 204 (2.4 GHz; reference embodiment: Tuya-certified module such as Skydance WT5 or equivalent) manages: mobile application control (iOS/Android via Tuya Smart Life or equivalent platform); voice assistant integration (Amazon Alexa, Google Assistant, Apple HomeKit/Siri); IFTTT conditional automation triggers; time-of-day scheduling via the RTC of the circadian controller 160; real-time weather API synchronization (e.g., OpenWeatherMap API or equivalent) that automatically adjusts the active scene to correspond with current outdoor meteorological conditions; and multi-device group synchronization for multi-panel installations. The present invention is not limited to the Tuya platform; any Wi-Fi or Bluetooth-enabled LED control module capable of the multi-channel output and scene automation functions described herein is within the scope of the invention.

The programmable circadian lighting scene presets managed by the circadian controller 160 include: Daylight (CCT 6,500K, high brightness, RGB blue supplemental); Morning Sunrise (CCT ramp 2,200K-5,500K over a programmable transition period with synchronized intensity increase simulating dawn); Afternoon (CCT 5,000K, moderate brightness); Golden Hour/Sunset (CCT 3,000K warm, 40% reduced brightness, RGB warm-amber elevated); Overcast/Cloudy (CCT 6,500K diffuse, RGB blue modulated); Night (RGB blue-dominant, CCT at minimum); Focus (CCT 6,500K, high brightness for cognitive task support); Calm (CCT 3,000K warm, reduced blue spectral exposure); and Energy (CCT 5,000K, elevated lux). All presets are programmable to execute on time-of-day schedules via the RTC, enabling automatic diurnal light cycling in support of circadian rhythm alignment without user intervention.

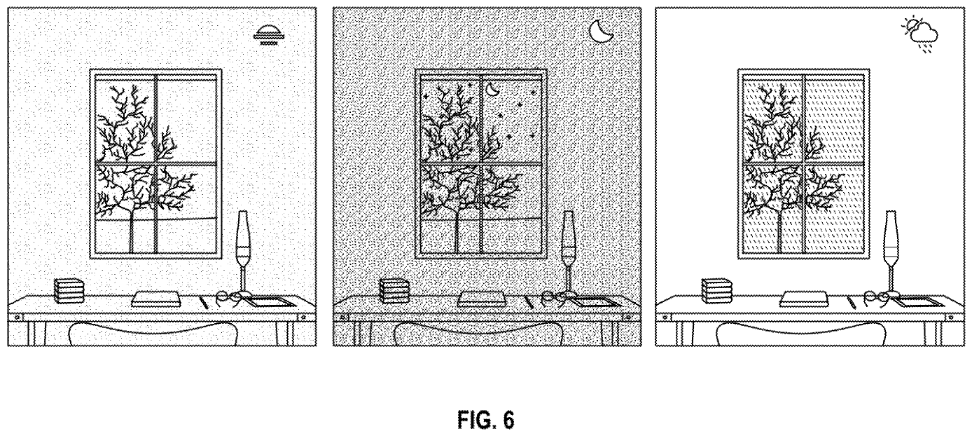

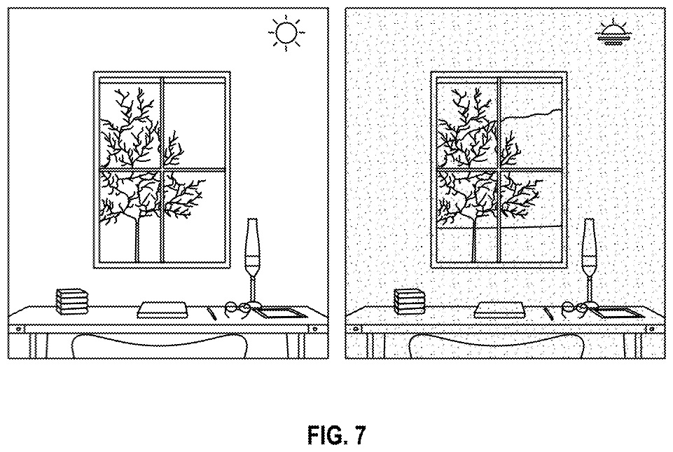

Referring now to FIG. 6 and FIG. 7, environmental front-elevation views of the system 100 are shown installed on an interior wall surface and operating under a plurality of the programmable lighting scene presets described above, illustrating the dynamic visual behavior of the apparatus as executed by the circadian controller 160 driving the tunable-white CCT LED array and the RGB LED array of the LED panel 140. In each view, the same graphic insert 120 is retained within the housing frame 102, and the differences in the rendered scene are produced solely by changes in the simultaneous combined spectral output of the CCT array and the RGB array under the control of the circadian controller 160 and the Wi-Fi smart LED controller 204, without substitution of the graphic insert 120 and without any change to the multi-layer optical assembly.

As shown in FIG. 6, the system 100 is depicted in three representative operating conditions. In a first view, the system 100 operates under the Daylight preset, wherein the circadian controller 160 drives the CCT array at a cool-white correlated color temperature with high luminous output and a supplemental RGB blue channel contribution, producing a bright, evenly illuminated scene across all four pane zones consistent with midday ambient daylight. In a second view, the system 100 operates under the Night preset, wherein the RGB blue channel is dominant, the CCT array is driven at minimum intensity, and the surrounding room is correspondingly dim, such that the scene within the pane zones assumes a dark, cool-toned, moonlit character with celestial cues visible through the transparent zones of the graphic insert 120. In a third view, the system 100 operates under the Overcast/Cloudy preset, wherein the CCT array is driven at a diffuse cool-white output with modulated RGB blue, producing the subdued, diffused, and desaturated illumination characteristic of cloudy or rainy outdoor conditions. In certain embodiments, the Overcast/Cloudy preset is automatically activated by the Wi-Fi smart LED controller 204 in response to real-time weather data retrieved from a weather API indicating cloud cover or precipitation at the geographic location of the system 100, thereby synchronizing the simulated outdoor scene with the actual current outdoor meteorological conditions.

As shown in FIG. 7, the system 100 is depicted in two additional representative operating conditions. In a first view, the system 100 operates under a midday Daylight or Afternoon preset, wherein the circadian controller 160 drives the CCT array at a cool-to-neutral correlated color temperature with high luminous output, producing bright, neutral-toned illumination across all four pane zones consistent with clear-sky daytime outdoor conditions. In a second view, the system 100 operates under the Golden Hour/Sunset preset, wherein the CCT array is driven at a warm correlated color temperature of approximately 3,000K, overall luminous intensity is reduced by approximately 40%, and the RGB warm-amber channel contribution is elevated, producing a naturalistic warm, golden, late-afternoon illumination character. The Golden Hour/Sunset preset may be executed automatically by the circadian controller 160 via the RTC as part of a scheduled diurnal transition, for example initiating a gradual shift from the Daylight preset to the Golden Hour/Sunset preset over a programmable transition period in the late afternoon without user intervention.

FIG. 6 and FIG. 7 collectively demonstrate that the system 100, without substitution of the graphic insert 120 and without any change to the housing frame 102, the front protective panel 110, the window partition element 104, the LED panel 140, or the back panel 170, is capable of reproducing a wide range of natural and celestial outdoor lighting conditions solely through coordinated independent control of the CCT array and the RGB array by the circadian controller 160. The views of FIG. 6 and FIG. 7 are illustrative of representative scene presets and are not limiting; additional scene presets, continuous transitions between presets, and user-customized scene profiles executed by the circadian controller 160 and the Wi-Fi smart LED controller 204 are likewise within the scope of the present invention.

The following alternate embodiments may be implemented in addition to, or in place of, any of the embodiments described above, without departing from the spirit and scope of the appended claims.

Ceiling-Mounted Skylight: In the ceiling-mounted skylight embodiment, the system 100 is oriented horizontally and installed on a ceiling surface using the hangers 206 engaging ceiling-mounted fasteners, without any modification to the system 100. The graphic insert 120 in this embodiment depicts an overhead sky, cloud, starfield, or celestial scene appropriate for overhead viewing. The housing frame 102, multi-layer optical assembly, and all control subassemblies are unchanged from the wall-mounted embodiment. This embodiment creates the visual experience of a skylight in interior spaces without structural roof modification and is enabled by the dual-hanger 206 rear mounting system described herein.

Multi-Panel Modular Wall Installation: In the multi-panel modular installation embodiment, two or more system 100 units are mounted in side-by-side, stacked, or grid arrangements using inter-panel mechanical connector hardware. Synchronized lighting control is achieved via the group function of the Wi-Fi smart LED controller 204 platform, enabling all units to operate as a unified system with synchronized scene transitions. This embodiment enables large-format window wall effects in commercial, hospitality, residential, and institutional settings. The graphic inserts 120 across multiple panels may be matched to form a continuous panoramic outdoor scene.

Arched and Custom Frame Shapes: The housing frame 102 may be fabricated in a non-rectangular profile—including arched top, circular porthole, elliptical, or other custom architectural shape—while retaining the same internal multi-layer optical assembly comprising the front protective panel 110, graphic insert 120, LED panel 140, and back panel 170. The window partition element 104 and all electrical and control subassemblies are likewise unchanged. This embodiment enables architectural integration with arched doorways, porthole windows, and other non-rectangular aperture forms common in residential and hospitality interiors.

Sensor-Integrated Adaptive Lighting: In this embodiment, the system 100 incorporates one or more of the following sensors operatively connected to the Wi-Fi smart LED controller 204: an ambient light sensor that measures room illumination and automatically adjusts LED panel 140 output to maintain consistent apparent window brightness; and an occupancy or proximity sensor that activates the system 100 upon detection of a room occupant and reduces output upon vacancy.

Motorized Accessory: A motorized roller blind or venetian blind accessory, controllable via the Wi-Fi smart LED controller 204 through the same mobile application used for lighting control, simulates the opening and closing of a real window blind. The motorized accessory may be programmed to open and close on a schedule synchronized with the active lighting scene. Motorized curtain or drape accessories on a rod mounted above the housing frame 102 constitute a related variant. These accessories are sold separately or as bundles and do not require modification to the system 100.

Flat-Pack and Self-Assembly Embodiment: The system 100 may be designed for flat-pack shipping and tool-free self-assembly using snap-fit or clip-together housing frame 102 components, reducing shipping volume and cost for e-commerce distribution. The multi-layer optical assembly, front protective panel 110, graphic insert 120, LED panel 140, and back panel 170, remain functionally unchanged; only the mechanical assembly sequence of the housing frame 102 is modified to accommodate flat-pack packaging.

Commercial and Healthcare Variant: Larger form factors and higher-lux configurations of the system 100 are contemplated for hospital rooms, office environments, elder care facilities, and therapeutic clinical settings. These variants may incorporate higher-power LED panels 140 for clinically relevant lux output, IES photometric curve-optimized luminous intensity distribution for daylight simulation efficacy, and clinical-grade photobiomodulation certification. The housing frame 102, window partition element 104, graphic insert 120, and control subsystem are functionally equivalent to the reference embodiment; sizing and luminous output are scaled to application requirements.

In one embodiment, a method of simulating a natural window comprises the following operational sequence. A user installs the housing frame on a wall surface or ceiling surface at a desired location and height using the integrated hangers, and selects and inserts a graphic insert carrying a printed outdoor scene rearward of the front protective panel. Upon powering the apparatus via the ON/OFF switch or mobile application, the controller activates the LED panel, which emits light forwardly through the light-diffusing element, through the graphic insert, and through the front protective panel, producing a window simulation visible to a room occupant. The opaque zones of the graphic insert block light transmission through the mullion and transom regions, reinforcing the structural window illusion. The user selects a desired lighting scene via the mobile application, voice assistant, or physical switch, causing the controller to simultaneously drive the tunable-white CCT array and the color RGB array of the LED panel to simulate the selected natural or celestial illumination condition. In a further aspect of this embodiment, the controller automatically executes a time-of-day lighting schedule, transitioning through morning sunrise, daylight, afternoon, golden hour, and night scene profiles without user intervention, simulating the natural diurnal progression of outdoor light. In a still further aspect, the controller retrieves real-time local weather data and automatically adjusts the active scene to correspond with current outdoor meteorological conditions, for example activating an overcast scene upon detection of cloud cover. The user may at any time replace the graphic insert with a different scene without tools, adapting the window simulation to a new outdoor environment without replacing any other component of the apparatus.

In an illustrative example of operation, a user mounts the Standard-size system 100 at standard window height, for example bottom edge at 900 mm from the floor, on the wall of a windowless basement home office. The hangers 206 engage wall anchors in standard drywall. A “Blue Sky with Trees” graphic insert 120 is inserted via the magnetic attachment mechanism immediately behind the front protective panel 110 and engaged until secure. The AC-DC adapter 202 is connected to a standard electrical outlet via the cable 150.

The user pairs the system 100 to a 2.4 GHz Wi-Fi network via the Tuya Smart Life mobile application and activates the Daylight scene. The circadian controller 160 drives the CCT array of the LED strip 402 at 6,500K and the RGB blue channel at approximately 20% intensity. Light propagates forwardly through the LED panel 140, through the graphic insert 120, transmitting the outdoor scene through the four transparent pane zones and blocking light at the window partition element 104 opaque zones, and through the front protective panel 110. The ON/OFF switch 404 on the frame edge allows manual power control at any time.

At 5:00 PM, the scheduled Golden Hour/Sunset transition initiates automatically via the RTC of the circadian controller 160: the CCT array shifts from 6,500K to 3,000K over 30 minutes, brightness reduces by 40%, and RGB warm-amber channels elevate, producing naturalistic warm late-afternoon golden light. At the user's discretion, weather synchronization retrieves current local weather data via the Wi-Fi smart LED controller 204 and adjusts the active scene in real time, for example switching to the Overcast preset upon detection of cloud cover in the user's location.

The foregoing description of the preferred embodiments of the present invention has been presented for purposes of illustration and description. It is not intended to be exhaustive or to limit the invention to the precise forms disclosed. Many modifications, variations, substitutions of equivalents, and adaptations will be apparent to those skilled in the art in light of the above teachings, and may be made without departing from the spirit and scope of the invention as defined by the appended claims. All dimensions, materials, component specifications, numerical values, ranges, trade names, example products, scene presets, and operating parameters disclosed herein, including without limitation those relating to the housing frame 102, window partition element 104, front protective panel 110, graphic insert 120, light-diffusing element 130, LED panel 140, power cable 150, circadian controller 160, back panel 170, AC-DC adapter 202, Wi-Fi smart LED controller 204, hanger 206, LED strips 402, and ON/OFF switch 404, are provided solely for purposes of illustration of preferred reference embodiments and shall not be construed as limiting the scope of the invention unless expressly recited in the claims. Features described with respect to any one embodiment may be combined with features of any other embodiment, and the invention is not limited to the particular combinations expressly described. The use of terms such as “window,” “frame,” “mullion,” “transom,” “pane,” “skylight,” and similar terminology is illustrative of one preferred application and shall not be construed to restrict the invention to window-simulation contexts; the invention is equally applicable to any non-digital layered optical scene simulation context, including without limitation skylight, nature scene, retail display, therapeutic, hospitality, healthcare, and wellness lighting applications. References to third-party platforms, protocols, services, or branded components, and any other identified product or service, are provided solely as non-limiting examples of suitable implementations, and equivalent platforms, protocols, services, or components now known or hereafter developed are within the scope of the invention. It is therefore intended that the scope of the invention be defined solely by the appended claims and their legal equivalents, and that all such modifications, variations, and equivalents be embraced therein.

What is claimed is:

1. A non-digital layered optical window simulation apparatus comprising:
a housing frame defining a viewing area;
a window partition element within the housing frame dividing the viewing area into a plurality of pane zones by at least one light-blocking opaque zone simulating a structural window element;
a multi-layer optical assembly within the housing frame comprising, a front protective panel, a graphic insert positioned rearward of the front protective panel and carrying a printed outdoor scene on a translucent substrate, an LED panel disposed rearward of the graphic insert and housing a plurality of LED strips, and a back panel; and
a circadian controller configured to simultaneously and independently drive a tunable-white CCT LED array and an RGB color LED array to generate a combined spectral output, wherein the combined spectral output produces an extended effective color temperature simulation range beyond a native tunable-white range,
by additive spectral blending of CCT and RGB channels,
thereby enabling simulation of natural and celestial lighting conditions across a range extending below 2,000K and above 7,000K equivalent.

2. The apparatus of claim 1, further comprising an ON/OFF switch on an exterior edge of the housing frame.

3. The apparatus of claim 1, wherein a physical inter-layer air gap of 1 millimeter to 10 millimeters is maintained between the rearward face of the graphic insert and the forward face of the LED panel, the air gap producing an optical depth perception in a viewer at normal viewing distance.

4. The apparatus of claim 1, wherein the LED panel comprises an integral light-diffusing element configured to distribute light uniformly across the entire viewing area and to eliminate visible LED point-source hot spots, such that no individual LED element is perceptible to a viewer at normal viewing distance, producing smooth and naturalistic illumination consistent with diffuse daylight through glass.

5. The apparatus of claim 1, wherein the LED strips comprise surface-mount LED elements operating at a DC voltage and having a color rendering index exceeding 90 and a tunable-white CCT range.

6. The apparatus of claim 1, wherein the circadian controller is configured to produce a combined effective light simulation range by simultaneously driving the CCT array and the RGB array, the range extending below the lower limit and above the upper limit of standard industry tunable-white LED technology, and including simulation of at least:
warm candlelight and firelight conditions via minimum CCT warm-white output combined with elevated RGB red and amber channel output;
golden-hour and sunset conditions via CCT warm-white output combined with RGB warm-amber output;
overcast and cloudy sky conditions via CCT cool-white output combined with elevated RGB blue channel output; and
clear high-altitude blue sky conditions via CCT cool-white output combined with substantially elevated RGB blue channel output.

7. The apparatus of claim 1, wherein the graphic insert is user-removable and user-replaceable without tools by engagement of an insert attachment mechanism selected from the group consisting of: magnetic coupling between rare-earth magnets in the housing frame and a corresponding magnetic element in a border region of the graphic insert; snap-fit retainers comprising spring-loaded clips on the housing frame engaging a receiver profile on the graphic insert; and screw-on fasteners securing the graphic insert border to the housing frame.

8. The apparatus of claim 1, further comprising at least two metal hangers fixed to a rear surface of the housing frame in a symmetrical arrangement.

9. The apparatus of claim 1, further comprising a wireless LED controller configured to provide: mobile application control of lighting scene, brightness, and color temperature; voice assistant integration; time-of-day scheduling via a real-time clock; and real-time weather data synchronization that automatically adjusts the active lighting scene to correspond with current outdoor conditions.

10. The apparatus of claim 9, wherein the wireless LED controller supports over-the-air firmware updates enabling post-deployment installation of new lighting scene profiles, API integrations, and smart home platform certifications without physical modification to the apparatus, and multi-device group synchronization for coordinated control of a plurality of apparatus units in a multi-panel installation.

11. The apparatus of claim 1, wherein the circadian controller stores a plurality of programmable lighting scene profiles executable on a time-of-day schedule, the profiles comprising at least:
a sunrise profile executing a gradual CCT ramp from a warm color temperature to a cooler color temperature over a programmable transition period with synchronized intensity increase, simulating natural dawn progression;
a daylight profile at a cool color temperature with high brightness and supplemental blue channel output;
a sunset profile at a warm color temperature with reduced brightness and elevated warm-amber RGB output;
a night profile with color LED dominant output at minimal intensity; and
at least one wellness preset configured to deliver a selected color temperature and spectral composition optimized for a defined cognitive or physiological effect.

12. The apparatus of claim 1, wherein the LED panel is configured to deliver sufficient luminous flux to simulate natural daylight illumination within an interior space.

13. The apparatus of claim 1, further comprising at least one sensor operatively connected to the wireless LED controller, the sensor selected from the group consisting of: an ambient light sensor configured to measure room illumination and adjust LED panel output to maintain consistent window appearance; and an occupancy sensor configured to activate the apparatus upon detection of a room occupant.

14. A method of simulating a natural window in an interior space, comprising:
mounting a housing frame on a wall surface or a ceiling surface;
positioning a graphic insert carrying a printed outdoor scene on a translucent substrate rearward of a front protective panel within the housing frame, the graphic insert incorporating at least one light-blocking opaque zone that divides a viewing area into a plurality of pane zones simulating structural window elements;
activating an LED panel disposed rearward of the graphic insert via a controller to emit light that propagates forwardly through the LED panel, through the graphic insert, and through the front protective panel to produce a window simulation visible to a room occupant;
simultaneously and independently driving a tunable-white LED array and a color LED array of the LED panel via the controller to simulate a selected natural or celestial illumination condition across a range extending beyond standard industry color temperature limits; and
blocking light transmission through the at least one opaque zone of the graphic insert, reinforcing the structural window illusion.

15. The method of claim 14, further comprising:
executing a programmable time-of-day lighting schedule via a real-time clock of a circadian controller to automatically transition between lighting scene presets corresponding to diurnal natural light progression; and
retrieving real-time local weather data via a wireless LED controller and automatically adjusting the active lighting scene preset to correspond with current outdoor meteorological conditions.

16. A non-digital optical illumination apparatus comprising:
a housing frame defining a viewing area;
a graphic insert disposed within the housing frame and carrying a printed scene on a translucent substrate;
an LED panel disposed rearward of the graphic insert and housing a plurality of LED strips comprising a tunable-white correlated color temperature array and a color LED array; and
a controller configured to simultaneously and independently drive the tunable-white array and the color array to produce a combined light output simulating natural and celestial illumination conditions across an effective color temperature range extending from below 2,000 kelvins equivalent to above 7,000 kelvins equivalent, the range being achieved by combined simultaneous output of the tunable-white array and the color array and being unachievable by either array operating alone.
